(19) United States
(12) Patent Application Publication
(10) Pub. No.: US 2006/0284658 A1
(43) Pub. Date: Dec. 21, 2006

(54) Rise and fall balancing circuit for tri-state inverters

(76) Inventor: Bradley J. Wright, Fort Collins, CO (US)

Correspondence Address: LSI LOGIC CORPORATION, 1621 BARBER LANE, MS: D-106, MILPITAS, CA, 95035, US

(21) Appl. No.: 11/157,299

(22) Filed: Jun. 20, 2005

(51) Int. Cl. H03B 1/00

(52) U.S. Cl. 327/170; 327/112

(57) ABSTRACT

Disclosed are various embodiments for adjusting both the rise and fall or both of an output pulse in an inverter circuit so that the output pulse has a length that matches the length of the input pulse. Stages of transistors having various sizes can be activated in both a pull-up circuit, a pull-down circuit or both to adjust the rise time and/or fall time of the output pulse.

### BACKGROUND OF THE INVENTION

a. Field of the Invention

The present invention pertains generally to electronic circuits and more particularly to a rise and fall balancing circuit.

b. Description of the Background

Skew introduced by electronic circuits can vary the rise and fall time of a pulse. As a result, the length of a input pulse can be different from the length of an output pulse that has traveled through an electronic circuit that introduces skew. In certain types of circuits, such as clock circuits, the pulse interval must remain constant from the input to the electronic circuit to the output. Many other types of circuits also require that the pulse interval remain constant as the pulse proceeds through various circuits.

### SUMMARY OF THE INVENTION

The present invention may comprise a method of controlling rise time and fall time of an output pulse that is produced in response to application of an input pulse to an inverter circuit comprising: applying the input pulse to an inverter circuit, the input pulse having a pulse length; providing a pull-up circuit disposed between a source voltage and the inverter circuit that has a plurality of pull-up transistors connected in parallel; activating a selected number of the plurality of pull-up transistors to adjust a rise time of the output pulse; providing a pull-down circuit disposed between the inverter circuit and ground that has a plurality of pull-down transistors connected in parallel; activating a selected number of the pull-down transistors to adjust a fall time of the output pulse so that the output pulse has a selected pulse length that substantially matches the pulse length of the input pulse.

The present invention may further comprise a method of controlling fall time of an output pulse that is produced in response to application of an input pulse to an inverter circuit comprising: applying the input pulse to an inverter circuit, the input pulse having a pulse length; providing a pull-up circuit disposed between a source voltage and the inverter circuit that has a pull-up transistor; activating the pull-up transistor; providing a pull-down circuit disposed between the inverter circuit and ground that has a plurality of pull-down transistors connected in parallel; activating a selected number of the pull-down transistors to adjust a fall time of the output pulse so that the output pulse has a pulse length that can be adjusted to substantially match the pulse length of the input pulse.

The present invention may further comprise a method of controlling rise time of an output pulse that is produced in response to application of an input pulse to an inverter circuit comprising: applying the input pulse to an inverter circuit, the input pulse having a pulse length; providing a pull-down circuit disposed between the inverter circuit and ground that has a pull-down transistor; activating the pull-down transistor; providing a pull-up circuit disposed between a source voltage and the inverter circuit that has a plurality of pull-up transistors connected in parallel; activating a selected number of the plurality of pull-up transistors to adjust a rise time of the output pulse so that the output pulse has a selected pulse length that substantially matches the pulse length of the input pulse.

### BRIEF DESCRIPTION OF THE DRAWINGS

In the drawings,

FIG. 1 is a graph of an input pulse to the circuit illustrated in FIG. 3.

FIG. 2 is an illustration of an output pulse of the circuit illustrated in FIG. 3.

FIG. 3 is an illustration of one embodiment.

FIG. 4A is an illustration of another embodiment.

FIG. 4B is a circuit diagram illustrating an alternative pull-up transistor configuration.

FIG. 5A is an illustration of still another embodiment.

FIG. 5B is a circuit diagram illustrating an alternative pull-down transistor configuration.

### DETAILED DESCRIPTION OF THE EMBODIMENTS

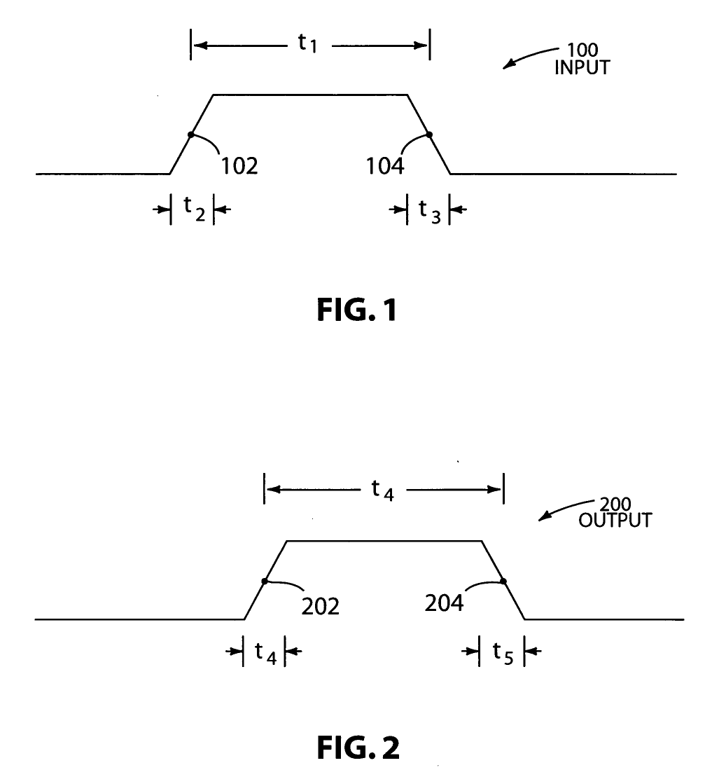

FIG. 1 is a graph of an input signal 100. The input signal 100 has a midpoint 102 during the rise delay of pulse 100 and a midpoint 104 during the fall delay of the pulse 100. The time (t₁) between points 102 and 104 is the measure of the pulse length of the input pulse 100. The time (t₂) between the beginning and the end of the rise delay is referred as the rise time. The fall time is indicated by the time (t₃).

FIG. 2 is a graph of an output pulse 200 that has traveled through a circuit. The difference between the midpoints 202 and 204 is the pulse length (t₄) of the output pulse 200. One of the problems of high speed input receivers, such as the input receivers in a high speed memory interface, is jitter. Jitter can be caused when the pulse length (t₁) at the input to the receiver does not match the pulse length (t₄) at the output of the receiver. The rise time (t₄) and fall time (t₅) of the output pulse 200 can be affected by the circuit as a result of processes used in constructing the circuit, voltage variations and temperature variations. It would therefore be advantageous to have the ability to control the rise times and fall times to ensure that the length of the output pulse 200 matches the length of the input pulse 100.

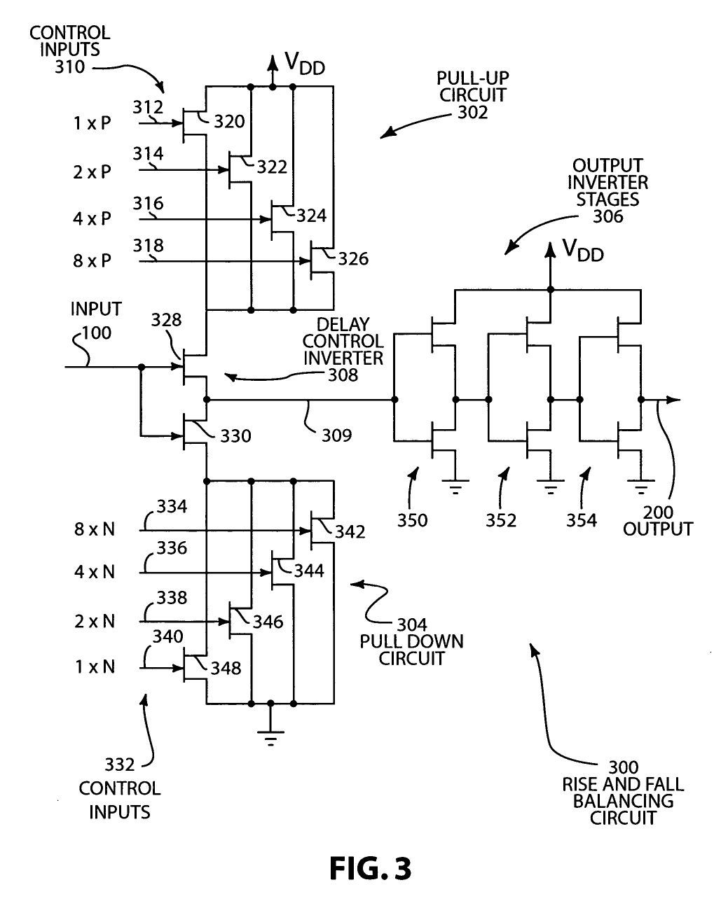

FIG. 3 is an embodiment of a rise and fall balancing circuit 300. The circuit 300 includes pull-up devices 302 and pull-down devices 304 that are connected to the source and ground, respectively, of the delay control inverter circuit 308. The output 309 of the delay control inverter circuit 308 is applied to output inverter stages 306 to produce the output 200. As shown in FIG. 3, the input signal 100 is applied to the delay control inverter circuit 308, which comprises transistors 328 and 330. The input pulse 100 is applied to the gates of transistors 328 and 330 and turns on transistors 328, 330. Power is supplied to the delay control inverter 308 by pull-up devices 302 that are connected to a supply voltage V_{DD}. The pull-up devices 302 comprise a series of parallel connected transistors 320, 322, 324, 326. The gates of each of these transistors 320, 322, 324, 326 are controlled by control input 310 which comprise control lines 312, 314, 316, 318. Each of the transistors 320-326 is a p-type transistor. Transistor 322 is twice as strong (has twice the surface area) as transistor 320. Transistor 324 is four times as strong (has four times the surface area) as transistor 320. Transistor 326 is eight times as strong (has eight times the surface area) as transistor 320. Control inputs 310 control whether the transistors 320-326 are turned on or off. By providing an input control signal on any one of the control lines 312, 314, 316, 318, the transistors 320, 322, 324, 326, respectively, will be turned on. One or more of the control lines 312-318 can be used to turn on one or more of the transistors 320-326. The pull-up devices 302 control the rise time (t₄) of the output pulse 200. For example, when a pulse 100 is applied to the delay control inverter 308, transistor 328 will turn on. If control line 318 is activated, transistor 326 will be turned on, which will allow the voltage to rise quicker at the output 309 of the delay control inverter 308, than it would if only control line 312 was turned on, which would turn on transistor 320. This is because transistor 320 is only one-eighth of the size and strength of transistor 326. Inputs 312-318 are scaled to a binary input, in which each successive transistor is twice as strong, so that 16 different levels of controls are provided by the four pull-up devices 302. Pull-up devices 302 are analogous to a RC circuit. As larger transistors are activated, the resistance is lowered and the rise time (t₄) of the output pulse 200 is reduced. The inverted pulse at 309 is applied to the three inverter stages 350, 352, 354 of the output inverter stages 306 to produce the output 200.

The pull-down devices 304, that are illustrated in FIG. 3, operate in a similar manner. Pull-down devices 304 are connected between the delay control inverter circuit 308 and ground. Control inputs 332, which comprise control lines 334, 336, 338, 340 control transistors 342, 344, 346, 348, respectively. The transistors of the pull-down circuit 304 are sized in a binary progression such that each successive transistor is twice as strong as the previous transistor. For example, transistor 346 is twice the size of transistor 348. Transistor 344 is four times the size of transistor 348. Transistor 342 is eight times the size of transistor 348. Again, the larger transistors are able to drive the pull-down circuit 304 faster than the smaller transistors. As more transistors are turned on in the pull-down circuit 304, by applying signals to the control inputs 332, the faster the pull-down circuit 304 is able to pull the falling portion of the pulse down. For example, when input pulse 100 is applied to the delay control inverter 308, the rising portion of the pulse connects the pull-down circuit 302 to the output 309. The falling portion of the input pulse 100 connects the pull-down device 304 to the output 309. The fall time (t₅) of the output pulse 200 is controlled by control inputs 334-340 which provide 16 different levels of control for the pull-down circuit 304. Again, since the transistors 342-348 are scaled in a binary fashion, controls 332 comprise binary type controls for controlling the pull-down circuit 304. As indicated above, the larger transistors provide more drive which reduces the pull-down time (t₅) so that the pull-down time (t₅) can be controlled with a high degree of precision and the temporal location of point 204 can be accurately controlled.

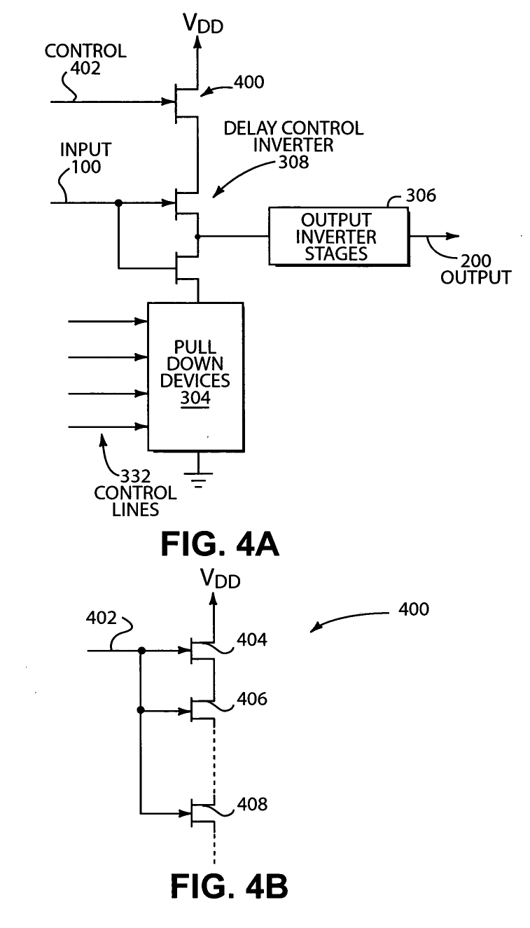

FIG. 4A is an illustration of another embodiment. As shown in FIG. 4A, an intermediate size transistor 400 is provided between the source (V_{DD}) and the delay control circuit 308. Control 402 is used to turn-on the transistor 400 so that the transistor 400 supplies the source voltage V_{DD} to the delay control inverter 308. Pull-down devices 304 are disposed between the delay control inverter 308 and ground. The pull-down devices 304 comprise the pull-down devices illustrated in FIG. 3 that have control inputs 332. Input pulse 100 is applied to the delay control inverter 308 which inverts the input pulse 100 at the output of the delay control inverter 308. The inverted pulse is then applied to the output inverter stages 306 to produce the output 200. The size of the transistor 400 is set to a medium size so that the pull-down devices 304 can be adjusted by control lines 332 to adjust the fall time (t₅) on output 200, so that the pulse length of the output signal 200 matches the pulse length of the input 100. In that manner, jitter is eliminated from the output signal 200. As voltage and temperature vary, the control inputs 332 can be adjusted to adjust for variations induced by these factors.

FIG. 4B is a circuit diagram of an alternative pull-up transistor configuration for pull-up transistor 400. As shown in FIG. 4B, the single transistor 400 can be replaced by a plurality of transistors, such as transistors 404, 406, 408, that are connected in series. In this fashion, a desired size of the pull-up transistor 400 can be achieved using the series connected transistors.

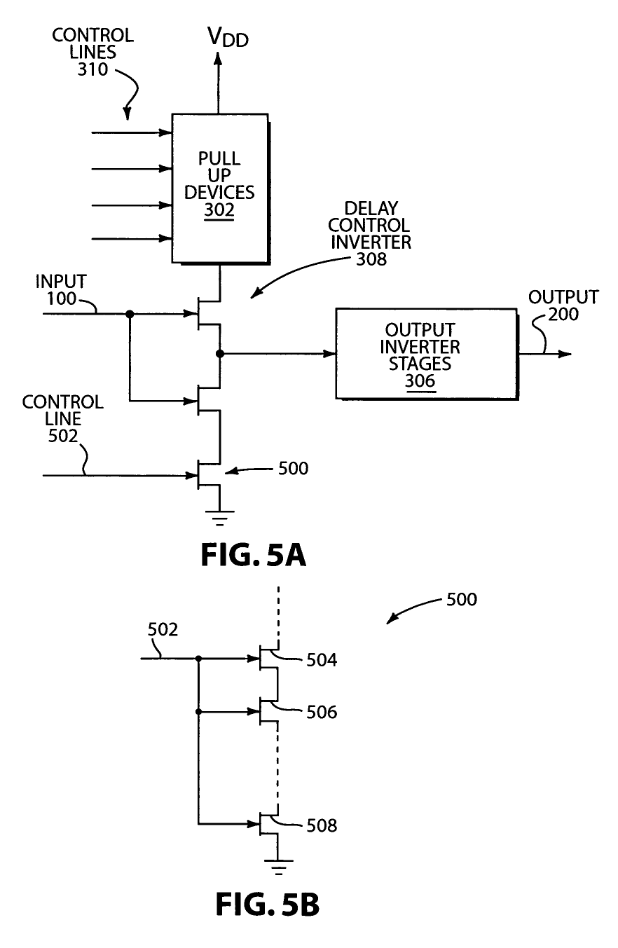

FIG. 5A is a schematic diagram of another embodiment. As shown in FIG. 5A, a medium size transistor 500 is placed between the delay control inverter 308 and ground. A control line 502 turns on the transistor 500. An input pulse 100 is applied to the delay control inverter 308 which inverts the input pulse 100 at the output of the delay control inverter 308. The output of the delay control inverter 308 is applied to the output inverter stages 306 to produce the output pulse 200. The fall time (t₅) of the output signal is fixed by the size of the transistor 500. However, the rise time (t₄) of the output pulse 200 can be adjusted by the pull-up devices 302 using control lines 310, as explained above. In this fashion, the length of the output pulse 200 can be adjusted to match the length of the input pulse 100 to avoid problems of jitter. Again, as conditions vary with respect to voltage or temperature of the circuitry, the rise time (t₄) of the output pulse 200 can be adjusted to ensure that the length of the output pulse matches the length of the input pulse.

FIG. 5B is a circuit diagram illustrating an alternative pull-down transistor configuration for pull-down transistor 500. As shown in FIG. 5B, a plurality of series connected transistors, such as transistors 504, 506, 508 can be used in place of a single transistor 500.

Therefore, various embodiments are disclosed that allow adjustment of either the rise or fall time, or both, of an inverter circuit to ensure that the length of the output pulse from the inverter matches the length of the input pulse. Although four stages in a binary type of control system are illustrated, other numbers of stages can be used such as two stages, or three stages, or more than four stages, in either the pull-up circuit or pull-down circuit. In addition, a binary progression of sizes does not have to be used, but any desired size can be used. In addition, the balancing circuits illustrated in FIGS. 3, 4 and 5 can be used in many different applications for balancing either the rise time or fall time, or both, of the output pulse for any desired purpose.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A method of controlling rise time and fall time of an output pulse that is produced in response to application of an input pulse to an inverter circuit comprising:
applying said input pulse to an inverter circuit, said input pulse having a pulse length;
providing a pull-up circuit disposed between a source voltage and said inverter circuit that has a plurality of pull-up transistors connected in parallel;
activating a selected number of said plurality of pull-up transistors to adjust a rise time of said output pulse;
providing a pull-down circuit disposed between said inverter circuit and ground that has a plurality of pull-down transistors connected in parallel;
activating a selected number of said pull-down transistors to adjust a fall time of said output pulse so that said output pulse has a selected pulse length that substantially matches said pulse length of said input pulse.

2. The method of claim 1 wherein said process of providing a pull-up circuit comprises a process of providing a pull-up circuit having a plurality of pull-up transistors that have strengths that follow a binary progression.

3. The method of claim 1 wherein said process of providing a pull-down circuit comprises a process of providing a pull-down circuit having a plurality of pull-down transistors that have strengths that follow a binary progression.

4. A method of controlling fall time of an output pulse that is produced in response to application of an input pulse to an inverter circuit comprising:
applying said input pulse to an inverter circuit, said input pulse having a pulse length;
providing a pull-up circuit disposed between a source voltage and said inverter circuit that has a pull-up transistor;
activating said pull-up transistor;
providing a pull-down circuit disposed between said inverter circuit and ground that has a plurality of pull-down transistors connected in parallel;
activating a selected number of said pull-down transistors to adjust a fall time of said output pulse so that said output pulse has a pulse length that can be adjusted to substantially match said pulse length of said input pulse.

5. The method of claim 1 wherein said process of providing a pull-up circuit comprises a process of providing a pull-up circuit having a plurality of pull-up transistors that are connected in series.

6. The method of claim 1 wherein said process of providing a pull-down circuit comprises a process of providing a pull-down circuit having a plurality of pull-down transistors that have strengths that follow a binary progression.

7. A method of controlling rise time of an output pulse that is produced in response to application of an input pulse to an inverter circuit comprising:
applying said input pulse to an inverter circuit, said input pulse having a pulse length;
providing a pull-down circuit disposed between said inverter circuit and ground that has a pull-down transistor;
activating said pull-down transistor;
providing a pull-up circuit disposed between a source voltage and said inverter circuit that has a plurality of pull-up transistors connected in parallel;
activating a selected number of said plurality of pull-up transistors to adjust a rise time of said output pulse so that said output pulse has a selected pulse length that substantially matches said pulse length of said input pulse.

8. The method of claim 7 wherein said process of providing a pull-up circuit comprises a process of providing a pull-up circuit having a plurality of pull-up transistors that have strengths that follow a binary progression.

9. The method of claim 7 wherein said process of providing a pull-up circuit comprises a process of providing a pull-up circuit having a plurality of pull-up transistors that have are connected in series.

10. A circuit for adjusting the rise time and fall time of an output pulse so that the pulse length of said output pulse can be adjusted to match the pulse length of an input pulse comprising:
an inverter circuit;
a pull-up circuit that is connected between said inverter circuit and a source voltage, said inverter circuit comprising a plurality of pull-up transistors that are connected in parallel that have control inputs for selecting said plurality of pull-up transistors to control the rise time of said output pulse;
a pull-down circuit that is connected between said inverter circuit and a source voltage, said inverter circuit comprising a plurality of transistors that are connected in parallel that have control inputs for selecting said plurality of pull-down transistors to control the fall time of said output pulse, so that said pulse length of said output pulse can be adjusted by adjusting said rise time and said fall time of said output pulse so that said pulse length of said output pulse substantially matches said pulse length of said input pulse.

11. A circuit for adjusting the fall time of an output pulse so that the pulse length of said output pulse can be adjusted to match the pulse length of an input pulse comprising:
an inverter circuit;
a pull-up circuit that is connected between said inverter circuit and a source voltage, said pull-up circuit comprising at least one pull-up transistor;
a pull-down circuit that is connected between said inverter circuit and a source voltage, said inverter circuit comprising a plurality of transistors that are connected in parallel that have control inputs for selecting said plurality of pull-down transistors to control fall time of said output pulse, so that said pulse length of said output pulse can be adjusted by adjusting said fall time of said output pulse so that said pulse length of said output pulse substantially matches said pulse length of said input pulse.

12. The circuit of claim 11 wherein said pull-up transistor comprises a single transistor.

13. The method of claim 11 wherein said pull-up transistor comprises a plurality of transistors connected in series.

14. A circuit for adjusting rise time of an output pulse so that a pulse length of said output pulse can be adjusted to match a pulse length of an input pulse comprising:
an inverter circuit;
a pull-down circuit that is connected between said inverter circuit and a source voltage, said pull-down circuit comprising at least one pull-down transistor;
a pull-up circuit that is connected between said inverter circuit and a source voltage, said inverter circuit comprising a plurality of pull-up transistors that are connected in parallel that have control inputs for selecting said plurality of pull-up transistors to control rise time of said output pulse so that said pulse length of said output pulse can be adjusted by adjusting said rise time of said output pulse so that said pulse length of said output pulse substantially matches said pulse length of said input pulse.

15. The circuit of claim 14 wherein said pull-down transistor comprises a single transistor.

16. The method of claim 14 wherein said pull-down transistor comprises a plurality of transistors connected in parallel.
